(19) United States
(12) Patent Application Publication
(10) Pub. No.: US 2025/0314959 A1
(43) Pub. Date: Oct. 9, 2025

(54) DEVELOPING APPARATUS, DEVELOPING METHOD, AND COMPUTER PROGRAM

(71) Applicant: Tokyo Electron Limited, Tokyo (JP)

(72) Inventors: Hirofumi GOTO, Kumamoto (JP); Katsuya HARA, Kumamoto (JP)

(73) Assignee: Tokyo Electron Limited, Tokyo (JP)

(21) Appl. No.: 19/170,138

(22) Filed: Apr. 4, 2025

(30) Foreign Application Priority Data
Apr. 4, 2024 (JP) 2024-060847

(51) Int. Cl. G03F 7/00; G03F 7/30

(52) U.S. Cl. CPC G03F 7/0025; G03F 7/3021

(57) ABSTRACT

A developing apparatus includes: a first nozzle including a first discharge port for a developing solution extending in a direction covering a width of a substrate; a moving mechanism that causes a first state where the first nozzle moves in a direction intersecting with an extending direction of the first discharge port discharging the developing solution; a first liquid contact surface that is in contact with a liquid film of the developing solution formed on the substrate in the first state; a second nozzle including a second discharge port for the developing solution; a rotation mechanism that rotates the substrate to cause a second state where the substrate rotates when the second discharge port is discharge the developing solution; and a second liquid contact surface that is in contact with the liquid film of the developing solution formed on the substrate in the second state.

### CROSS-REFERENCE TO RELATED APPLICATION(S)

The present application claims priority to and incorporates by reference the entire contents of Japanese Patent Application No. 2024-060847 filed in Japan on Apr. 4, 2024.

### FIELD

Exemplary embodiments disclosed herein relate to a developing apparatus, a developing method, and a computer program.

### BACKGROUND

In manufacturing a semiconductor device, a developing process is performed such that a developing solution is supplied to a resist film formed on a semiconductor wafer (hereinafter, referred to as a wafer) as a substrate to form a pattern. This developing process may be performed by discharging the developing solution from a discharge port of a nozzle while moving the nozzle on the wafer so that a lower surface of the nozzle on which the discharge port is formed is brought into contact with a liquid surface of a liquid pool of the developing solution supplied to the wafer. Japanese Laid-open Patent Publication No. 2022-24733 discloses a developing apparatus configured to perform such processing.

### SUMMARY

A developing apparatus includes: a holding part configured to hold a substrate; a first nozzle including a first discharge port for a developing solution extending in a lateral direction over a length covering a width of the substrate; a moving mechanism configured to cause a first state in which the first nozzle is moved in a direction intersecting with an extending direction of the first discharge port during discharge of the developing solution from the first discharge port to the substrate; a first liquid contact surface that forms an opening edge part of the first discharge port and is in contact with a liquid film of the developing solution formed on the substrate in the first state; a second nozzle including a second discharge port for the developing solution in which a length in the extending direction of the first discharge port is formed to be shorter than the first discharge port; a rotation mechanism configured to rotate the holding part to cause a second state in which the substrate is rotated during discharge of the developing solution from the second discharge port to the substrate; and a second liquid contact surface that forms an opening edge part of the second discharge port and is in contact with the liquid film of the developing solution formed on the substrate in the second state.

### BRIEF DESCRIPTION OF DRAWINGS

FIG. 1 is a plan view illustrating a developing apparatus according to the present disclosure;

FIG. 2 is a longitudinal sectional back view of a spin chuck illustrated in FIG. 1;

FIG. 3 is a longitudinal sectional side view of the spin chuck;

FIG. 4 is a longitudinal sectional side view of the spin chuck;

FIG. 5 is a schematic plan view illustrating a first developing method;

FIG. 6 is a schematic plan view illustrating the first developing method;

FIG. 7 is a schematic plan view illustrating the first developing method;

FIG. 8 is a schematic plan view illustrating the first developing method;

FIG. 9 is a longitudinal sectional side view illustrating supply of a developing solution in the first developing method;

FIG. 10 is a longitudinal sectional side view illustrating supply of the developing solution in the first developing method;

FIG. 11 is a longitudinal sectional side view illustrating supply of a cleaning liquid in the first developing method;

FIG. 12 is a longitudinal sectional side view illustrating supply of the developing solution in the first developing method;

FIG. 13 is a longitudinal sectional side view illustrating supply of the developing solution in the first developing method;

FIG. 14 is a schematic plan view illustrating a second developing method;

FIG. 15 is a schematic plan view illustrating the second developing method;

FIG. 16 is a schematic plan view illustrating the second developing method;

FIG. 17 is a schematic plan view illustrating the second developing method;

FIG. 18 is a schematic plan view illustrating the second developing method;

FIG. 19 is a longitudinal sectional side view illustrating a nozzle bus;

FIG. 20 is a lateral sectional plan view illustrating the nozzle bus;

FIG. 21 is a perspective view illustrating a cleaning part of the nozzle bus;

FIG. 22 is a longitudinal sectional side view illustrating a cleaning process by the nozzle bus;

FIG. 23 is a longitudinal sectional side view illustrating an alternative example of the nozzle bus; and

FIG. 24 is a longitudinal sectional side view illustrating an alternative example of the nozzle bus.

### DESCRIPTION OF EMBODIMENTS

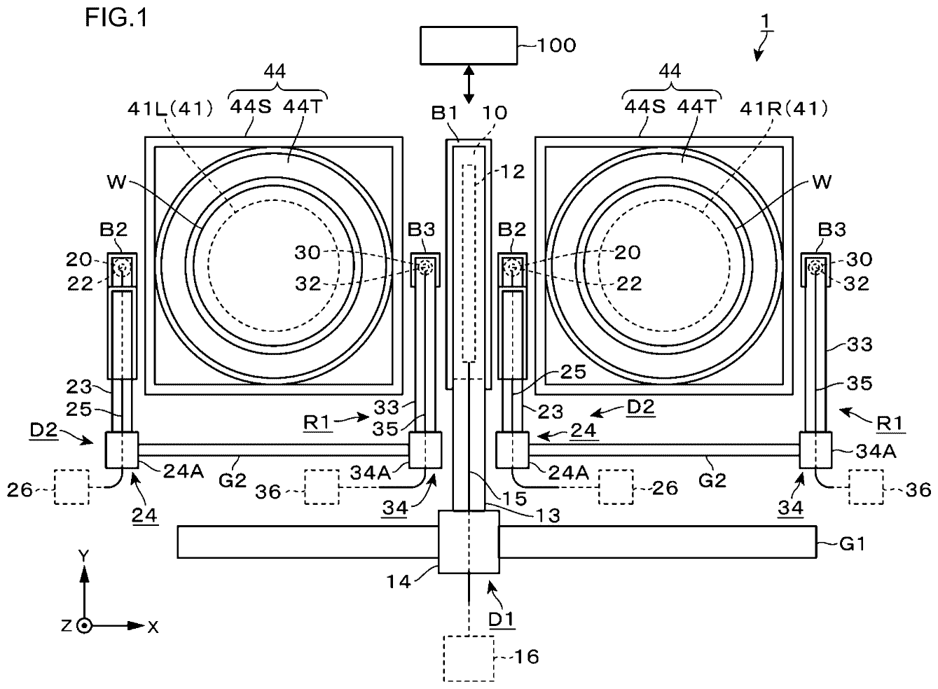

The following describes a developing apparatus 1 as an exemplary embodiment of a developing apparatus according to the present disclosure. FIG. 1 is a plan view illustrating the developing apparatus 1, and illustrates a state in which nozzles 10, 20, and 30 (described later) are respectively disposed in nozzle buses B1, B2, and B3. In the present embodiment, an XYZ orthogonal coordinate system is used for description. The X-direction may be referred to as a lateral direction, a side where a spin chuck 41R as a substrate holding part is disposed in the X-direction may be referred to as a right side, and a side where a spin chuck 41L is disposed may be referred to as a left side. The Y-direction may be referred to as a front and rear direction, and a side where moving mechanisms 14, 24, and 34 are disposed may be referred to as a front side, and a side where the spin chucks 41R and 41L are disposed may be referred to as a rear side. In a case of explaining matters common to both of the spin chucks 41R and 41L, they may be simply referred to as spin chucks 41.

The spin chucks 41R and 41L are disposed separately on the left and right on an upper surface of the developing apparatus 1. A wafer (substrate) W with an exposed resist film (not illustrated) disposed on its surface is transferred to the developing apparatus 1, the wafer W is placed on each of the spin chucks 41R and 41L, and a developing process by supplying a developing solution and a cleaning process by supplying a cleaning liquid are performed in order. The developing apparatus 1 according to the present embodiment includes a first and a second developing solution supply mechanisms D1 and D2 configured to supply the developing solution by the first and the second nozzles 10 and 20 having different forms, and a cleaning liquid supply mechanism R1 configured to supply the cleaning liquid by the cleaning nozzle 30.

The cleaning liquid supply mechanism R1 includes a cleaning nozzle 30 that discharges a cleaning liquid as deionized water, for example, a nozzle arm 33 including the cleaning nozzle 30 disposed on a leading end side, a moving mechanism 34 configured to support a bottom end side of the nozzle arm 33 to be appropriately displaced, and a processing liquid supply mechanism 36 that supplies the cleaning liquid to the nozzle 30. The cleaning liquid supply mechanism R1 is disposed for each of the spin chucks 41R and 41L, and the nozzle bus B3 as a standby position of the cleaning nozzle 30 is disposed on the right side of each of the spin chucks 41R and 41L.

Similarly to the cleaning liquid supply mechanism R1, the first and the second developing solution supply mechanisms D1 and D2 respectively include the first and the second nozzles 10 and 20 that discharge the developing solution, nozzle arms 13 and 23 including the first and the second nozzles 10 and 20 disposed on a leading end side, the moving mechanisms 14 and 24 configured to support the bottom end side of the nozzle arms 13 and 23 to be appropriately displaced, and processing liquid supply mechanisms 16 and 26 that supply the developing solution to the nozzles 10 and 20. The second developing solution supply mechanism D2 is disposed for each of the spin chucks 41R and 41L, and the nozzle bus (second standby part) B2 as a standby position of the nozzle 20 is disposed on the left side of each of the spin chucks 41R and 41L. Thus, the wafer W held by one of the spin chucks 41R and 41L is processed by the second nozzle 20 disposed on the left side in a standby state, and the cleaning nozzle 30 disposed on the right side in a standby state when viewed from the spin chuck 41.

Each of the moving mechanisms 14, 24, and 34 that displaces a position of the nozzle as described above is constituted of a lifting/lowering mechanism that is connected to the nozzle arms 13, 23, and 33 and lifts/lowers the nozzle arms 13, 23, and 33, and a horizontal moving mechanism that is connected to the lifting/lowering mechanism and horizontally moves the lifting/lowering mechanism to the left and right. In the drawing, the lifting/lowering mechanism is denoted by a reference numeral given to the moving mechanism to which a character “A” is added.

A lifting/lowering mechanism 24A of the second developing solution supply mechanism D2 and a lifting/lowering mechanism 34A of the cleaning liquid supply mechanism R1 are moved to the left and right by horizontal moving mechanisms respectively disposed on the front side of the spin chucks 41R and 41L. The horizontal moving mechanisms respectively connected to the lifting/lowering mechanisms 24A and 34A are collectively indicated as one horizontal moving mechanism G2 so long as they are disposed corresponding to the same spin chuck 41. A lifting/lowering mechanism 14A of the first developing solution supply mechanism D1 is connected to a horizontal moving mechanism G1 that is disposed across the two horizontal moving mechanisms G2 on the front side thereof, and configured to be moved to the left and right by the horizontal moving mechanism G1. Thus, the moving mechanism 14 is positioned on the front side of the moving mechanisms 24 and 34.

The first developing solution supply mechanism D1 is used in common by the spin chucks 41R and 41L. As described later, the spin chucks 41R and 41L are respectively disposed in cups 44, so that it can be said that the first developing solution supply mechanism D1 is used in common by the two cups 44. The nozzle bus (first standby part) B1 as a standby position of the nozzle 10 is disposed between the spin chucks 41R and 41L in a plan view, and the nozzle buses B3, B1, and B2 are arranged from the left to the right in order between the spin chucks 41R and 41L. Due to this, at the time of moving from the nozzle bus B1 to the spin chucks 41R and 41L to supply the developing solution, the nozzle 10 passes through an upper region of the nozzles 30 and 20 at standby positions to move to the left and right. The nozzle buses B1 to B3 each include a recessed part to store a lower part of the nozzle for standby.

The following briefly describes the lifting/lowering mechanism 14A representing the lifting/lowering mechanisms 14A, 24A, and 34A having a common configuration. Although not illustrated, the lifting/lowering mechanism 14A includes a motor, a ball screw that is rotated by the motor and disposed in the Z-direction, and a guide rail that guides movement. The moving mechanism 14 and the nozzle arm 13 are appropriately displaced in the Z-direction due to rotation of each ball screw the rotation amount of which is controlled by a controller 100 (described later). The horizontal moving mechanisms G1 and G2 have the same configuration as that of each lifting/lowering mechanism except for a direction in which the ball screw and the guide rail extend.

Supply routes 15, 25, and 35 connecting the nozzles 10, 20, and 30 with the processing liquid supply mechanisms 16, 26, and 36 are attached over the nozzle arms 13, 23, and 33 and the moving mechanisms 14, 24, and 34. The following describes the supply route 15 as a representative thereof, a valve (not illustrated) is disposed in the supply route 15, and the processing liquid supply mechanism 16 includes a tank that retains the developing solution that is previously manufactured for developing a resist film, and a flow volume adjusting mechanism for adjusting a flow volume of the developing solution. As described above, the nozzle 10 is configured to discharge the developing solution of a flow volume set in advance.

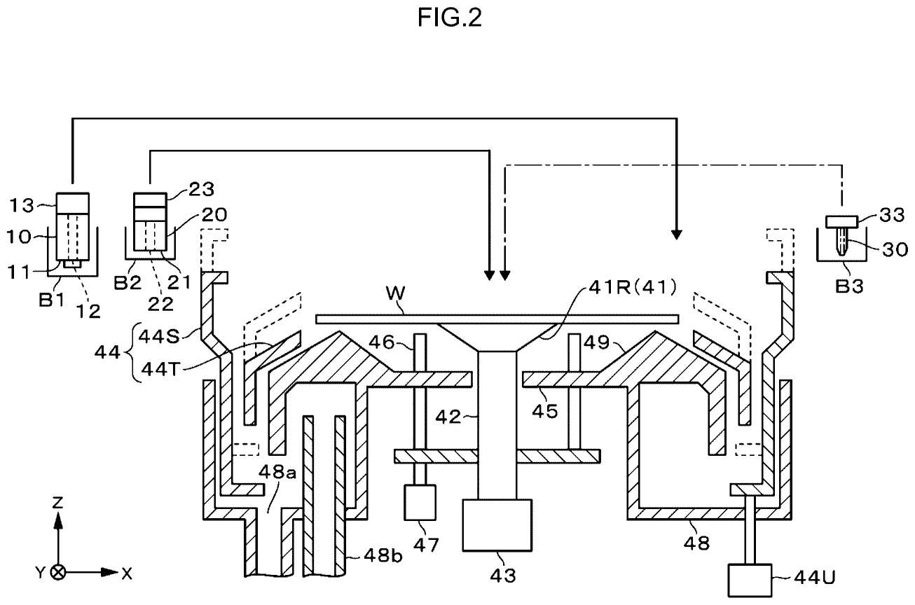

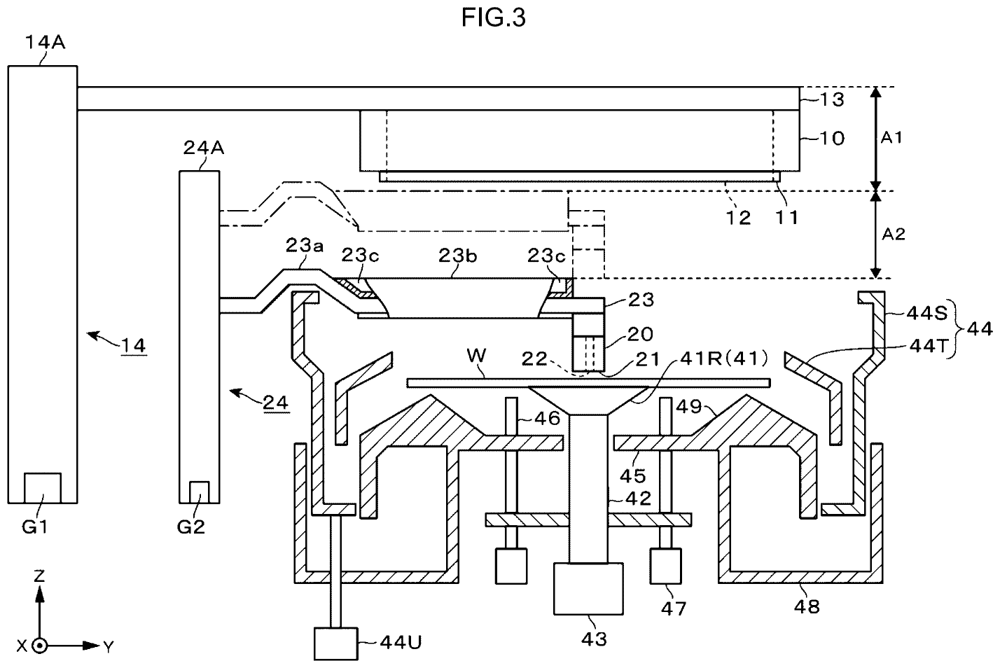

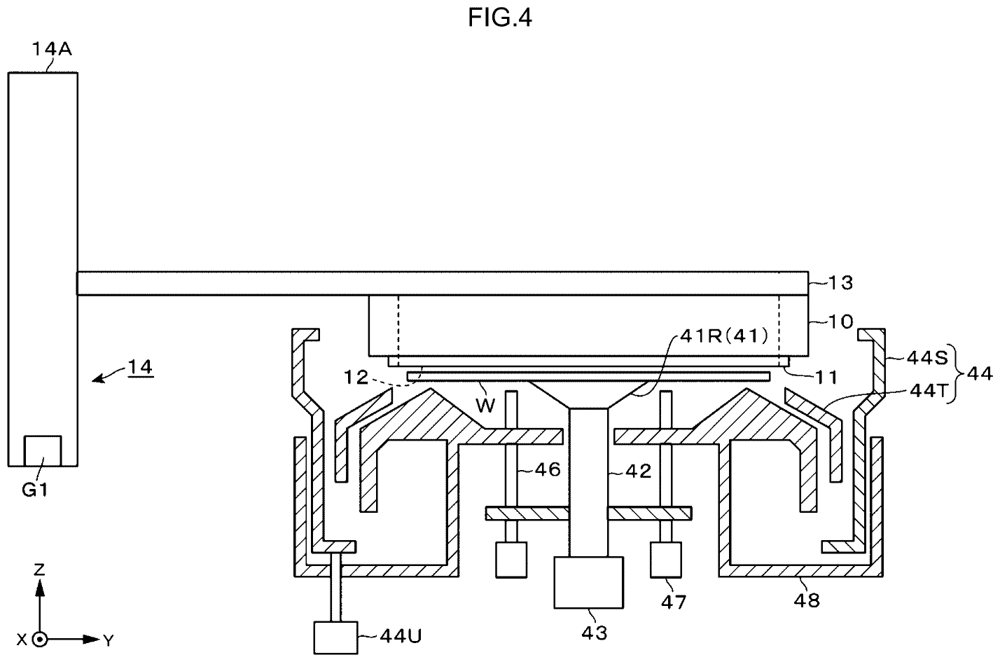

FIG. 2 is a longitudinal sectional back view of the spin chuck 41L illustrated in FIG. 1, and also illustrates the nozzles 10, 20, and 30 that supply a processing liquid to the wafer W supported by the spin chuck 41L. FIG. 3 and FIG. 4 are longitudinal sectional side views of the spin chuck 41L illustrated in FIG. 1. FIG. 3 illustrates the first developing solution supply mechanism D1 at the time of horizontal movement and the second developing solution supply mechanism D2 at the time of supplying the developing solution (described later) by solid lines, and illustrates the second developing solution supply mechanism D2 at the time of horizontal movement (described later) by alternate long and short dash lines. FIG. 4 illustrates the first developing solution supply mechanism D1 at the time of supplying the developing solution.

The nozzles 10, 20, and 30 respectively includes discharge ports 12, 22, and 32 opening at the center of respective leading end surfaces (lower end surfaces) 11, 21, and 31 facing downward. These discharge ports 12, 22, and 32 discharge the developing solution and the cleaning liquid supplied from the processing liquid supply mechanisms 16, 26, and 36 via the supply routes 15, 25, and 35. The nozzle 30 includes a circular discharge port that has a relatively small diameter and opens vertically downward.

The nozzle 10 has a rectangular parallelepiped shape, and a height thereof is longer than a width of a shorter side of the leading end surface 11. The discharge port 12 of the nozzle 10 has a long slit shape extending orthogonally to the X-direction (that is, the lateral direction) as a moving direction of the nozzle 10, and extends in the Y-direction (that is, the lateral direction) over a length covering a diameter as a width of the wafer W supported by the spin chucks 41R and 41L. The leading end surface 11 of the nozzle 10 has a rectangular frame shape surrounding the discharge port 12.

The nozzle 20 has a cylindrical shape, and a height thereof is smaller than the height of the nozzle 10. The leading end surface 21 of the nozzle 20 is an annular surface constituting a hole edge of the discharge port 22. As a supplementary explanation, the circular discharge port 22 opens at the center of a circular surface as the leading end surface 21, and a diameter of the circular surface described above is smaller than a radius of the wafer W. Thus, the width (in this case, the diameter) of a portion having a maximum width of the discharge port 22 is smaller than a size in a length direction of the slit of the discharge port 12. An area of the leading end surface 21 is smaller than an area of the surface of the wafer W. For example, it may be 1 to 15%, 1 to 11%, or 1 to 3% of the area of the surface of the wafer W. An area (opening area) of the discharge port 22 may be about 0.3% to 5% of the area of the leading end surface 21.

A discharge amount of the developing solution of the nozzle 10 including the relatively large discharge port 12, that is, a supply amount of the developing solution to the nozzle 10, is larger than that to the nozzle 20. Both of the nozzles 10 and 20 supply the developing solution in a state in which the leading end surfaces 11 and 21 that discharge the developing solution are in contact with a liquid film of the developing solution formed on the wafer W (liquid contact state).

As illustrated in FIG. 2, the spin chuck 41 is connected to a rotation mechanism 43 via a rotating shaft 42. The spin chuck 41 is configured to be freely rotated by the rotation mechanism 43 about a vertical axis in a state of holding the wafer W. The diameter of the wafer W is, for example, 300 mm. A horizontal disc 45 surrounding the rotating shaft 42 is disposed on a lower side of the spin chuck 41. In the drawing, reference numeral 46 denotes a lifting/lowering pin passing through the disc 45, which is lifted/lowered by a lifting/lowering mechanism 47 and delivers the wafer W between the spin chuck 41 and a transfer mechanism for the wafer W (not illustrated).

A liquid receiving part 48 configured to form an annular recessed part over the entire outer circumference of the disc 45 is disposed, and a drain port 48a is opened in the liquid receiving part 48. The liquid receiving part 48 constitutes a bottom part of the cup 44 (described later). A ring body 49 is disposed on a peripheral part of the disc 45, the ring body 49 having an upper end close to a back surface of the wafer W and being formed to have a chevron shape in a vertical cross-sectional view to guide dropped liquid to the liquid receiving part 48. An exhaust pipe 48b for exhausting air from the cup 44 is disposed in the liquid receiving part 48, and a downstream side of the exhaust pipe 48b is connected to an exhaust passage of a factory via a valve that switches an exhaust volume by changing an opening (not illustrated).

The developing apparatus 1 also includes the cup 44 that surrounds a side circumference of the wafer W placed on the spin chuck 41. The cup 44 is constituted of an outer cup 44S, an inner cup 44T disposed inside it, and the liquid receiving part 48 described above. When the outer cup 44S is lifted/lowered by a lifting/lowering mechanism 44U, the inner cup 44T is lifted/lowered in conjunction with the outer cup 44S, and a relative height of the inner cup 44T with respect to the outer cup 44S is not changed and kept the same at a lifted position and a lowered position. The inner cup 44T and the outer cup 44S at the lifted position and the lowered position are respectively indicated by chain lines and solid lines in FIG. 2. Hereinafter, the lifted position and the lowered position of the inner cup 44T and the outer cup 44S may be referred to as a lifted position and a lowered position of the cup 44.

The outer cup 44S and the inner cup 44T respectively have an angular cylindrical shape and a cylindrical shape opening in an upper and lower direction, have upper and lower openings having a rectangular shape and a circular shape, and are disposed to extend upward from a region surrounded by an outside wall of the liquid receiving part 48. A width of the upper opening of the inner cup 44T is larger than the diameter of the wafer W supported by the spin chuck 41, and an upper portion of the inner cup 44T is inclined toward an upper inner side in a vertical cross-sectional view to form an inclined surface. The upper portion of the inner cup 44T is, at the lowered position, positioned below the wafer W not to obstruct movement of the first nozzle 10 that moves as described later, and at the lifted position, positioned above the wafer W to receive droplets scattered from the wafer W by the inclined surface and guide them toward the liquid receiving part 48 on the lower side.

An upper end of the outer cup 44S is higher than an upper end of the inner cup 44T. An upper portion of the outer cup 44S is higher than the wafer W placed on the spin chuck 41 even at the lowered position, and suppresses scattering of the developing solution to the surroundings when a developing process is performed by the first nozzle 10 in a state in which the cup 44 is at the lowered position. More specifically, as illustrated in FIG. 4, the nozzle 10 disposed to be close to the upper side of the wafer W at the time of supplying the developing solution is disposed inside the upper portion as a rectangular frame of the outer cup 44S at the lowered position, and the center in a longitudinal direction thereof moves along the diameter parallel with the lateral direction of the wafer W to supply the developing solution without being in contact with the outer cup 44S.

In performing processing by the nozzle 20 or the cleaning nozzle 30, the cup 44 is positioned at the lifted position (refer to FIG. 3), and can receive liquid scattered from the wafer W due to rotation of the wafer W during this processing by an inner peripheral surface of the inner cup 44T.

As a moving route in a case of supplying the developing solution and the like by using the nozzle arms 13, 23, and 33, first, the nozzle arms 13, 23, and 33 in a standby state are lifted to retreat the nozzles 10, 20, and 30 from the nozzle buses B1, B2, and B3. Subsequently, the nozzle arms 13, 23, and 33 are moved in the horizontal direction (that is, the lateral direction) to an immediately upper side of discharge positions, and are lowered to place the nozzles 10, 20, and 30 at the discharge positions. The nozzles 10, 20, and 30 at the discharge positions are disposed so that lower parts thereof are accommodated in the cup 44 positioned at the lifted position or the lowered position. Specifically, the discharge positions of the nozzles 10 and 20 are positions where the leading end surfaces 11 and 21 are close to the surface of the wafer W and in contact with a liquid film of the developing solution formed on the surface of the wafer W. The discharge position of the nozzle 30 is a position where the leading end surface 31 is relatively far from the wafer W, and the leading end surface 31 is not in contact with a liquid film of the cleaning liquid discharged onto the wafer W. Arrows in FIG. 2 indicate such moving routes of the nozzles 10, 20, and 30.

When the nozzles 10, 20, and 30 finish discharging the liquid and return to the nozzle buses, they return to the nozzle buses by being lifted, horizontally moved, and lowered in order. That is, it is the reverse of the moving routes indicated by the arrows. However, the nozzle 10 is used by the spin chucks 41L and 41R in common, so that, after the nozzle 10 finishes discharging the liquid to the wafer W of one of the spin chucks 41, the nozzle 10 may be lifted, horizontally moved, and lowered to be moved to the discharge position for the wafer W of the other one of the spin chucks 41.

In FIG. 3, a moving region of the nozzle 10 at the time of horizontal movement is indicated as a horizontal moving region A1, and a moving region of the nozzle 20 at the time of horizontal movement is indicated as a horizontal moving region A2. The horizontal moving region A2 is also a moving route of the nozzle 30 at the time of horizontal movement. The horizontal moving region A1 is positioned above the horizontal moving region A2. The following describes the reason why the horizontal moving region A1 of the nozzle 10 is set above the horizontal moving region A2 of the nozzles 20 and 30.

First, as described above, the nozzle 10 includes, at the lower end, the discharge port 12 that is long in the Y-direction. To discharge the developing solution from each part of the discharge port 12 with high uniformity, a length of a flow channel formed between the discharge port 12 and a downstream end of the supply route 15 connected to an upper side of the nozzle 10 is required to be relatively large. That is, to utilize natural diffusion of the developing solution in the Y-direction while flowing through the flow channel formed in the nozzle 10, the height of the nozzle 10 is relatively high. On the other hand, each of the discharge ports of the nozzles 20 and 30 have a small diameter as described above, so that the nozzles 20 and 30 are not required to be formed to be high.

If the nozzle 10 is not disposed in the developing apparatus 1 and only the nozzles 20 and 30 are disposed therein, a lifting/lowering distance of the nozzles 20 and 30 is assumed to be a, the lifting/lowering distance required for moving the nozzles 20 and 30 between the discharge positions and the nozzle buses B2 and B3. As compared with the lifting/lowering distance a, a lifting/lowering distance is relatively large in a case of setting the horizontal moving region A2 for the nozzles 20 and 30 above the horizontal moving region A1 in the developing apparatus 1. That is, an increase amount of the lifting/lowering distance is large due to an operation of avoiding the high nozzle 10, which is unnecessary for primary processing of the nozzles 20 and 30. The large lifting/lowering distance increases the size of the lifting/lowering mechanism. That is, it is not desirable to set the horizontal moving region A2 above the horizontal moving region A1 from the viewpoint that a large-sized moving mechanism is required due to an operation unnecessary for primary processing of the nozzles 20 and 30.

From the viewpoint of reducing power consumption of each moving mechanism for moving the nozzle and reducing dusts, the moving mechanism is preferably downsized. Specifically, it is preferable to use a small-sized motor to configure the moving mechanism, or use a thin ball screw or guide rail. Due to the differences in the shape as described above, the nozzles 20 and 30 are lighter than the nozzle 10. If the moving mechanisms 24 and 34 that move the nozzles 20 and 30 are positioned on the front side of the moving mechanism 14 that moves the nozzle 10, the nozzle arms 23 and 33 that support the nozzles 20 and 30 are required to have relatively large lengths, so that it may be difficult to downsize the moving mechanisms 24 and 34. Thus, as described above, the moving mechanism 14 is disposed on the front side of the moving mechanisms 24 and 34.

It is assumed that the horizontal moving region A2 for the nozzles 20 and 30 moved by the moving mechanisms 24 and 34 disposed on the front side is set above the horizontal moving region A1 for the nozzle 10 moved by the moving mechanism 14 disposed on the rear side. In such a case, the horizontal moving region A1 is used as a lifting/lowering region for the nozzles 20 and 30, so that the nozzle 10 and the nozzle arm 13 connected thereto are moved in the horizontal moving region A1 while avoiding interference with the nozzles 20 and 30 and the nozzle arms 23 and 33 connected thereto. In this way, operation settings of the nozzles 10, 20, and 30 are made complicated to prevent interference. To prevent a failure described above, the horizontal moving region A1 for the nozzle 10 is preferably set above the horizontal moving region A2 for the nozzles 20 and 30.

Moving control for each nozzle may be performed such that the nozzle 10 and the nozzle arm 13 moving in the horizontal moving region A1 may overlap with the nozzles 20 and 30 and the nozzle arms 23 and 33 moving in the horizontal moving region A2. However, to securely prevent interference between the nozzles and the nozzle arms, it is preferable to prevent such overlapping from being caused. As a specific example, when the nozzle 10 moves from the nozzle bus B1 or the spin chuck 41L in the horizontal moving region A1 to process the wafer W on the spin chuck 41R on the right side, the nozzles 20 and 30 that are disposed corresponding to the spin chuck 41R are caused to stand by in the nozzle buses, and the nozzle 10 passes through the upper side of the nozzle 20 on standby to move onto the wafer W.

As illustrated in FIG. 3, in supplying the developing solution or the cleaning liquid by the nozzle 20 or the nozzle 30, the liquid scatters to the surroundings due to rotation of the wafer W, so that the cup 44 moves to the lifted position indicated by dotted lines in FIG. 2 to prevent scattering of the liquid. A bending part 23a is formed on the nozzle arm 23 to prevent contact with the outer cup 44S at the lifted position when the nozzle 20 is disposed at the discharge position. The bending part 23a is a part formed by being bent in a chevron shape when viewed from the X-direction, and a recessed part is formed on a lower surface of the nozzle arm 23 due to the bending part 23a. When the nozzle 20 is disposed at the discharge position of the developing solution, the upper end of the outer cup 44S enters the recessed part to prevent the contact described above.

A liquid receiving part 23b is formed on the bending part 23a and a leading end of the nozzle arm 23, the liquid receiving part 23b configured to be able to retain the developing solution dropped from the nozzle 10 passing through the upper side of the nozzle arm 23. The liquid receiving part 23b is disposed across an oblique surface on a leading end side of the bending part 23a and the leading end side of the nozzle arm 23, and a recessed part 23c opening upward is formed on an upper surface thereof. The recessed part 23c is disposed between an upper surface position of a head top part of the bending part 23a and an upper surface position of the leading end of the nozzle arm 23 in a lateral view. A depth of the recessed part 23c is gradually deepened from a bottom end side toward the leading end side on the upper side of the bending part 23a, and substantially uniform on a side closer to the leading end than the bending part 23a of the nozzle arm 23.

As illustrated in FIG. 1, in the developing apparatus 1, the controller 100 connected to each part of the developing apparatus 1 as described above is disposed. The controller 100 is, for example, a computer, and includes a computer program storage part (not illustrated). The computer program storage part stores a computer program that controls a developing process for the wafer W in the developing apparatus 1. The computer program described above may be recorded in a computer-readable storage medium, and installed into the controller 100 from the storage medium.

A command (each step) is incorporated in the computer program so that a control signal is output to each part of the developing apparatus 1 by the installed computer program. This control signal controls movement of the first and the second developing solution supply mechanisms D1 and D2 or the cleaning liquid supply mechanism R1, supply of the developing solution or the cleaning liquid, and a nozzle cleaning operation by the nozzle buses B1 to B3. The controller 100 includes one or a plurality of control circuits to execute the step of the computer program.

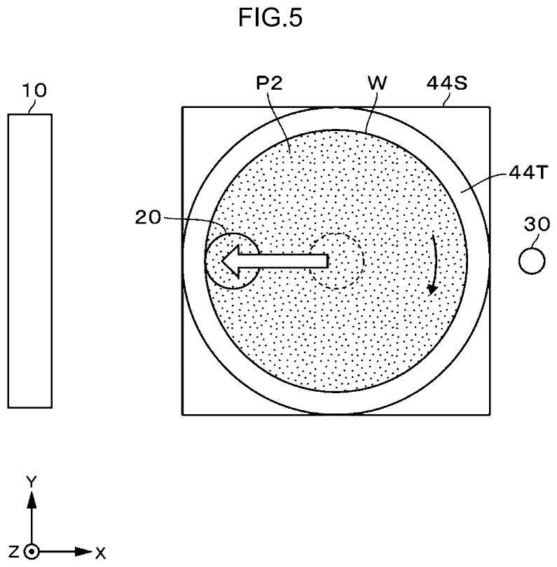

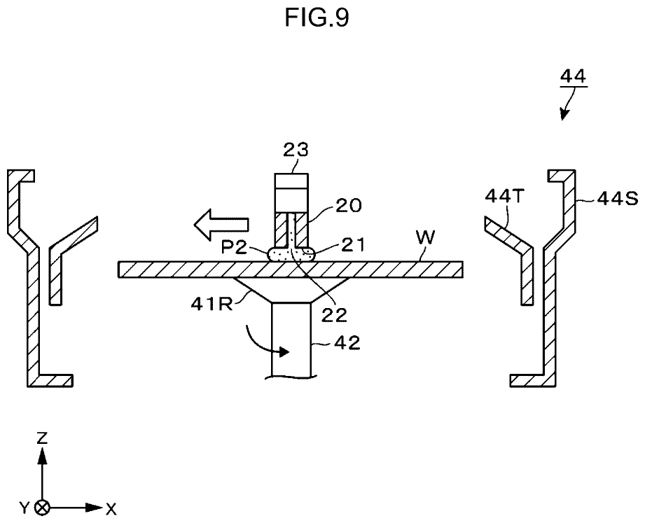

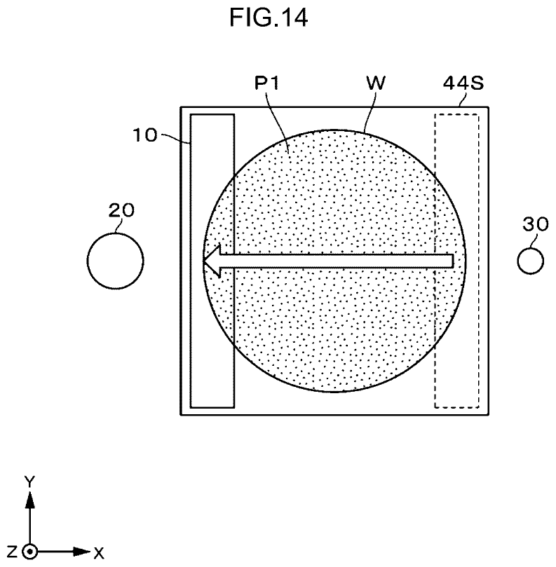

The following describes a first developing method of the developing apparatus 1 with reference to FIG. 5 to FIG. 13 illustrating this method. FIG. 5 to FIG. 8 are schematic plan views illustrating the first developing method, which illustrate only the outer cup 44S positioned above the wafer W and the inner cup 44T at the lifted position, and do not illustrate the inner cup 44T at the lowered position. The same applies to FIG. 14 and succeeding drawings. FIG. 9 to FIG. 13 are longitudinal sectional side views illustrating a method for supplying a liquid in the first developing method, and stippling is added to the developing solution in these FIG. 5 to FIG. 13. The same applies to the succeeding drawings. For explanation, a positive direction in the X-direction may be indicated as the X-direction (+), and a negative direction in the X-direction may be indicated as the X-direction (−). Each plan view illustrates processing on the wafer W placed on the spin chuck 41R.

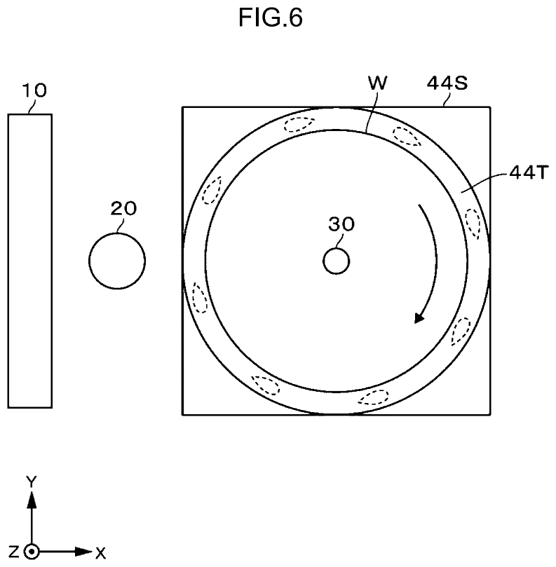

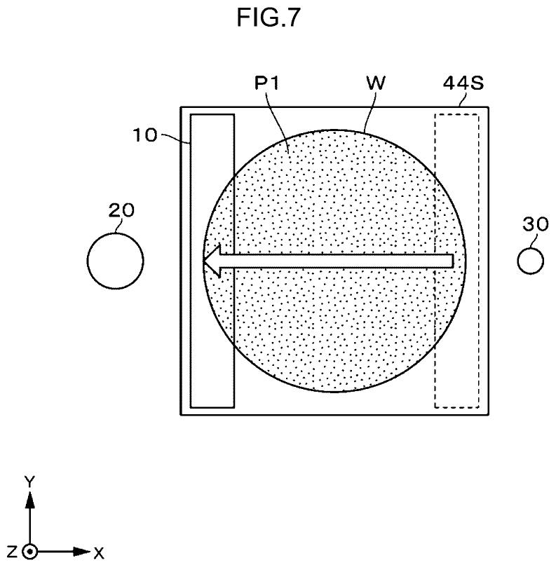

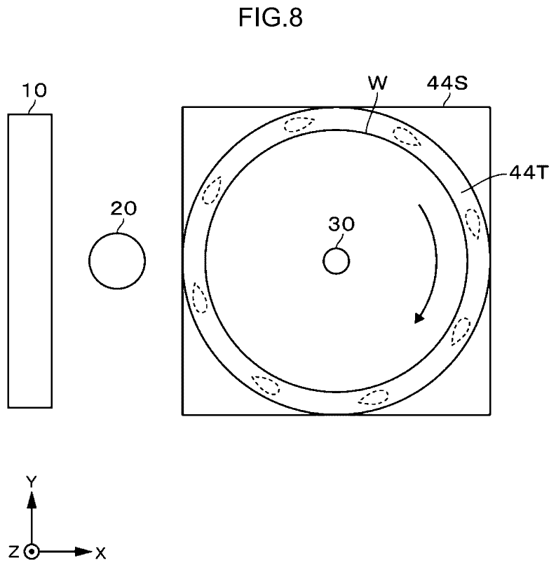

To start the developing process, first, the wafer W transferred by a substrate transfer mechanism (not illustrated) is disposed on the projecting lifting/lowering pin 46 to be lowered, and caused to be adsorbed and held by the spin chuck 41R. For the wafer W held by the spin chuck 41, the developing solution is supplied by the nozzle 20 (FIG. 5)→the cleaning liquid is supplied and removed by the nozzle 30 (FIG. 6)→the developing solution is supplied by the nozzle 10 (FIG. 7)→and the cleaning liquid is supplied and removed by the nozzle 30 (FIG. 8).

To describe a series of pieces of processing in more detail, the nozzle 20 is moved from the nozzle bus B2 to the discharge position of the developing solution on the wafer W, and the discharge port 22 is disposed right above a center part of the wafer W. In a state in which the cup 44 is disposed at the lifted position as illustrated in FIG. 5 and FIG. 9, the developing solution is discharged from the discharge port 22 of the nozzle 20 by the processing liquid supply mechanism 26 (FIG. 1). In discharging the developing solution, the discharge port 22 is horizontally moved along the radius of the wafer W from the center of the wafer W toward the X-direction (−) on the nozzle bus B2 side in a state in which the wafer W is rotated at a relatively low speed by the rotation mechanism 43 (second state). Due to this, a liquid film P2 of the developing solution is formed on the wafer W.

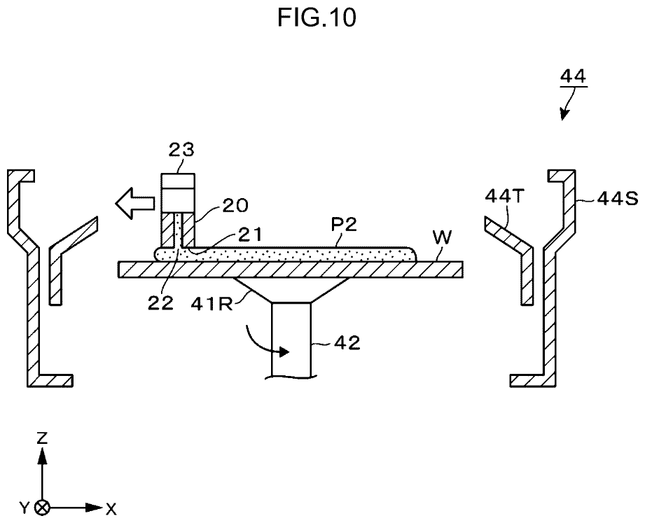

As illustrated in FIG. 9 and FIG. 10, in supplying the developing solution by the nozzle 20, the developing solution is discharged from the discharge port (second discharge port) 22 in the liquid contact state while the wafer W and the discharge port 22 are mutually moved. The liquid contact state means a state in which the leading end surface (second liquid contact surface) 21 forming a hole edge of the discharge port 22 is in contact with the liquid film P2. In this way, the leading end surface 21 is in contact with the liquid film P2 in a state in which the nozzle 20 is moved and the wafer W is rotated, so that a shearing stress toward an opposite direction of a rotation direction of the wafer W and a shearing stress toward the moving direction of the nozzle 20 are applied to a region below the leading end surface 21 on the liquid film P2. Due to working of these stresses, the developing solution is agitated in the region, and a developing reaction proceeds relatively rapidly.

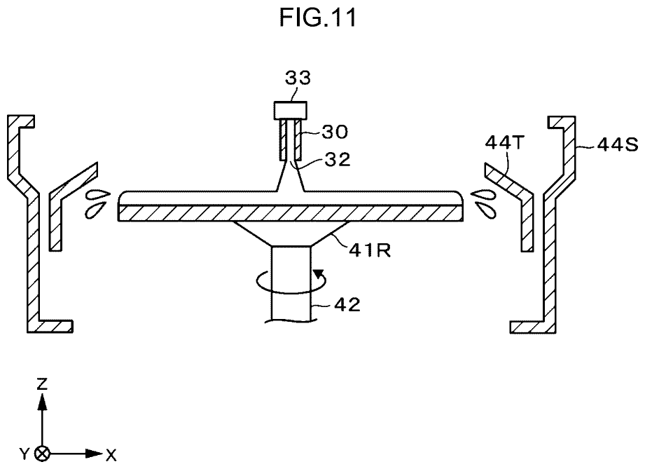

When the nozzle 20 reaches a peripheral part of the wafer W and the leading end surface 21 passes through the entire surface of the wafer W, that is, when the developing process on the entire surface of the wafer W is completed, discharge of the developing solution is stopped, and the nozzle 20 is lifted and returned to the nozzle bus B2. Subsequently, the cleaning liquid is supplied to the center part of the wafer W by the nozzle 30 that has moved from the nozzle bus B3 to an upper side of the center part of the wafer W, and the wafer W rotates relatively quickly. Due to this, the developing solution is shaken off together with the cleaning liquid toward an outer circumference of the wafer W, and removed from the surface of the wafer W (FIG. 6, FIG. 11).

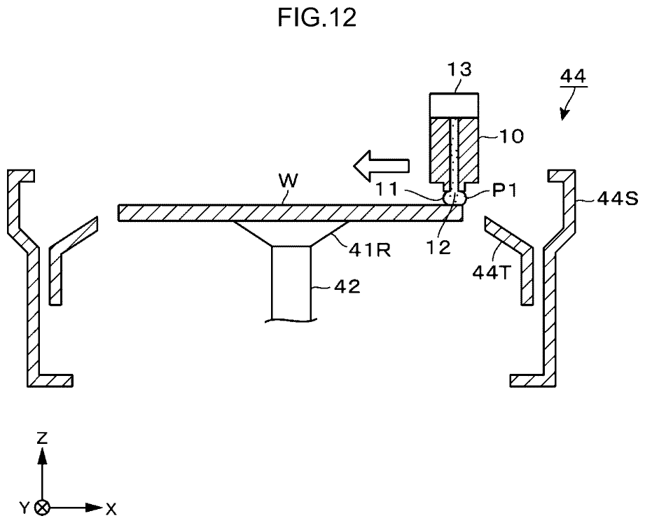

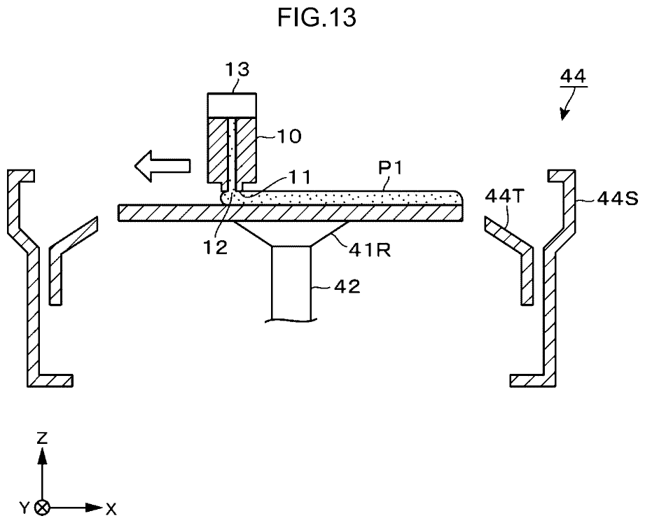

Thereafter, discharge of the cleaning liquid is stopped, and the nozzle 30 is lifted and returned to the nozzle bus B3. Even after supply of the cleaning liquid is stopped, the wafer W is continuously rotated and the cleaning liquid is shaken off to be removed. When the wafer W is dried, rotation of the wafer W is stopped. The cup 44 is disposed at the lowered position, the nozzle 10 moves from the nozzle bus B1 to the discharge position of the wafer W on the right end side in the outer cup 44S, and discharge of the developing solution is started (FIG. 12). The nozzle 10 moves to the left, and the liquid film P1 of the developing solution is formed on the wafer W (FIG. 7, FIG. 13). In the liquid contact state in which the leading end surface (first liquid contact surface) 11 of the nozzle 10 is in contact with the liquid film Pl, movement of the nozzle 10 and discharge of the developing solution from the discharge port (first discharge port) 12 are continued. When the liquid film P1 is formed on the entire wafer W and the nozzle 10 moves to a left end part in the outer cup 44S in a plan view, discharge of the developing solution is stopped, and the nozzle 10 returns to the nozzle bus B1 or moves to an upper side of the wafer W to process the wafer W on the spin chuck 41L. After the developing process has proceeded for a predetermined time while the wafer W is in a stationary state, the cleaning liquid is supplied by the nozzle 30 to remove the liquid film P1 similarly to a removing process of the liquid film P2, and development of the resist film by the first developing method is ended.

The wafer W on the spin chuck 41L is also processed similarly to the wafer W on the spin chuck 41R, but the nozzle 10 is positioned on a left end part in the outer cup 44S to start discharge of the developing solution, and discharges the developing solution while moving toward a right end part in the outer cup 44S to form the liquid film P1 on the wafer W. After moving to the right end part in the outer cup 44S, the nozzle 10 returns to the nozzle bus B1 or moves toward an upper side of the spin chuck 41R to process the next wafer W. The flow channel in the nozzle 10 having a large height as described above is large, so that the developing solution tends to remain. However, the nozzle 10 does not pass through the upper side of the wafer W on which the liquid film P1 has been formed, so that, even if the developing solution remaining in the flow channel is dropped from the nozzle 10, it does not fall onto the liquid film P1 that has been already formed. Thus, a failure is prevented from occurring in the developing process. At the time of passing through the horizontal moving region A1 toward the nozzle bus B1 and the like after processing the wafer W on the spin chuck 41R, even if the developing solution is dropped from the nozzle 10 onto the nozzle arm 23 on standby, the recessed part 23c of the liquid receiving part 23b receives it and prevents contamination of the nozzle arm 23. Due to this, at the time of supplying the developing solution by the nozzle 20, unintended dropping of the developing solution from the nozzle arm 23 onto the wafer W can be suppressed.

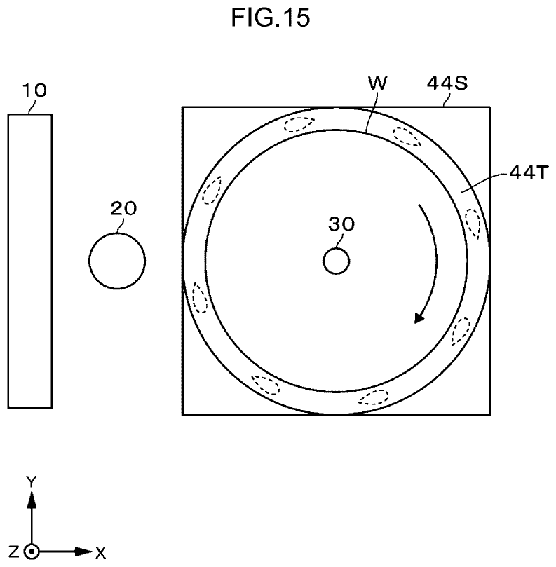

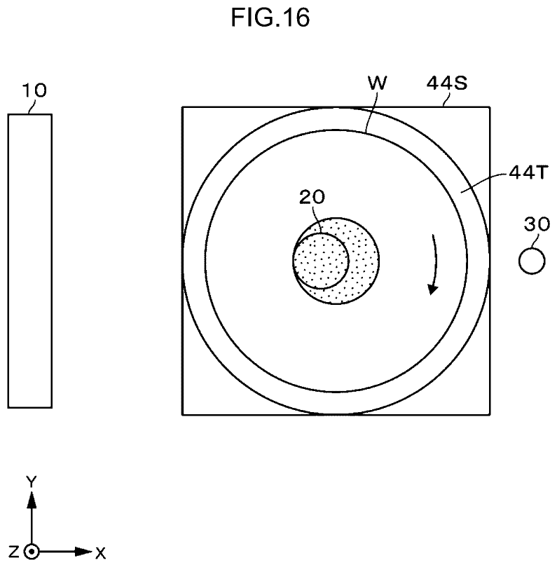

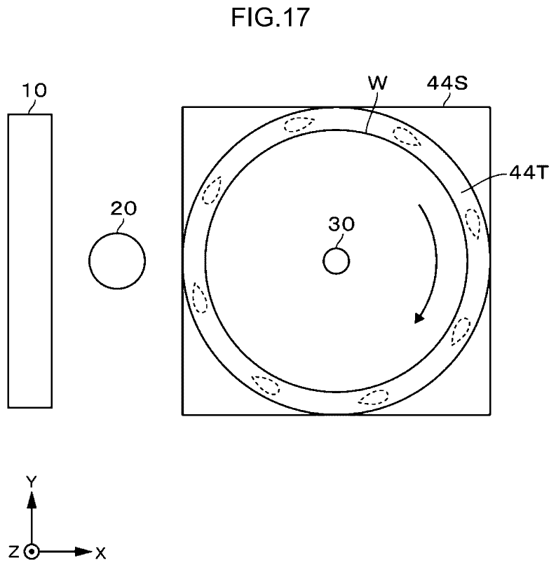

Subsequently, the following describes a second developing method with reference to FIG. 14 to FIG. 17 illustrating this method. FIG. 14 to FIG. 17 are schematic plan views illustrating the second developing method. In the second developing method, differently from the first developing method, the developing solution is supplied by the nozzle 10 first, and the developing solution is supplied by the nozzle 20 thereafter. Specifically, for the wafer W held by the spin chuck 41R, the developing solution is supplied by the nozzle 10 (FIG. 14)→the cleaning liquid is supplied and removed by the nozzle 30 (FIG. 15)→the developing solution is supplied by the nozzle 20 (FIG. 16)→and the cleaning liquid is supplied and removed by the nozzle 30 (FIG. 17).

To describe the series of pieces of processing in more detail, as illustrated in FIG. 14, supply of the developing solution by the nozzle 10 is performed similarly to supply of the developing solution by the nozzle 10 in the first developing method. The subsequent cleaning process (supply and removal of the cleaning liquid) is performed similarly to the cleaning process in the first developing method. For the subsequent developing process by the nozzle 20, for example, the nozzle 20 is disposed above the center part of the wafer W, and the leading end surface 21 of the nozzle 20 is brought into contact with the liquid film P2 of the discharged developing solution (FIG. 16). At this time of contact, the wafer W is rotated but the nozzle 20 is kept stationary. Thus, by locally causing agitation action of the developing solution at the center part of the wafer W, a developing reaction at the center part is relatively largely advanced. Thereafter, after stopping discharge of the developing solution and moving the nozzle 20 to the nozzle bus B2, the cleaning process is performed similarly to the former cleaning process.

The following describes the reason why development is performed two times by using the nozzles 10 and 20 as in the first developing method and the second developing method described above. First, for explanation about the first developing method, a resist film surface has various kinds of liquid repellency and lyophilicity for the developing solution depending on a type of a resist. That is, an interfacial tension between the developing solution at the time of being supplied to the resist and the resist film surface varies depending on the type of the resist. The nozzle 10 includes the discharge port 12 having the shape described above, so that it can supply the developing solution to the wafer W with high uniformity. However, unintended flow of the developing solution immediately after being supplied to the wafer W may be caused depending on an interfacial tension thereof, so that in-plane uniformity in the processing may be lowered. A region that is not covered by the developing solution may be generated within a plane of the wafer W.

To prevent this failure, development by the nozzle 20 is performed first. As described above, due to the shearing stress caused by rotation of the wafer W and movement of the nozzle 20, development proceeds in a state in which the developing solution flows relatively largely between the nozzle 20 and the wafer W below the nozzle 20. Due to this, influence of the interfacial tension described above is suppressed, and development is performed with relatively high uniformity at each part of the surface of the wafer W at a stage where development by the nozzle 20 is ended. When the resist film is wetted by development by the nozzle 20 and part of the resist film is melted, working of the interfacial tension described above is weakened at the time when the processing by the nozzle 10 is started thereafter, so that the developing solution can be supplied to the plane of the wafer W with high uniformity using the nozzle 10, and the in-plane uniformity in the processing can be enhanced.

Next, the following describes the second developing method. Due to variation in in-plane processing on the wafer W from when the resist film is formed until development is performed, shapes of patterns may vary at respective positions in a radial direction of the wafer W even if development is uniformly performed within the plane of the wafer W. That is, if development is uniformly performed as described above, patterns in some regions of the wafer W may be formed as if progress of the development thereof is delayed as compared with patterns in other regions. On the wafer W indicated in the processing examples in FIG. 14 to FIG. 17, a pattern in a region at the center part is formed as if progress of development thereof is delayed as compared with patterns in other regions. Thus, in the second developing method, after development is performed with high uniformity within the plane of the wafer W using the nozzle 10 first for the wafer W, a developing reaction at the center part is largely advanced by limitedly disposing the nozzle 20 above the center part of the wafer W to perform the processing, and in-plane uniformity of the pattern is enhanced at the time when the processing ends.

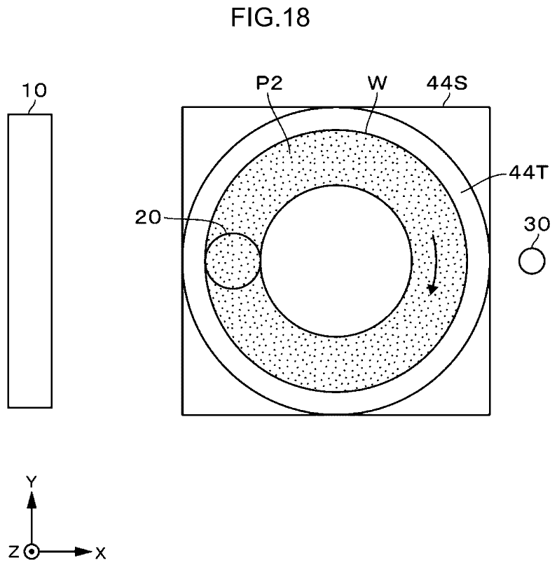

In the second developing method, disposition of the nozzle 20 is optional. To enhance the in-plane uniformity of the pattern, the nozzle 20 may be disposed at a position where a developing reaction is desired to be largely advanced within the plane of the wafer W. As illustrated in FIG. 18, the nozzle 20 may be disposed on a peripheral part to largely advance the development on the peripheral part. In a case of relatively largely advancing a developing reaction on part of the plane of the wafer W as described above, the nozzle 20 is not limited to be stationary, but may be moved along the radial direction of the wafer W as described in the first developing method. At this point, a progress degree of the development at each part of the wafer W may be adjusted by adjusting a moving speed of the nozzle 20, a rotational speed of the wafer W, and a flow volume of the developing solution to be discharged.

In the first developing method and the second developing method, the cleaning process (supplying the cleaning liquid and shaking off the cleaning liquid) is performed between the first developing process and the second developing process, but the first development and the second development may be successively performed without performing the cleaning process. In the first developing method using the nozzle 20 first, it is shown that the nozzle 20 is moved so that the leading end surface 21 passes through the entire surface of the wafer W, but it is not prohibited that the nozzle 20 is kept stationary and locally disposed at part of the plane of the wafer W to perform development as described in the second development. However, it is preferable to move the nozzle 20 to perform the processing for a purpose of performing the first developing method described above.

The developing process by the developing apparatus 1 is not limited to the developing process using both of the nozzle 10 and nozzle 20 as in the first and the second developing methods. If sufficient in-plane uniformity of the pattern can be achieved by performing development using only one nozzle, only one nozzle may be used for the purpose of increasing throughput of the apparatus. As described above, with the developing apparatus 1 according to the present disclosure that includes the first developing solution supply mechanism D1 including the nozzle 10 and the second developing solution supply mechanism D2 including the nozzle 20, various developing methods can be performed, so that convenience of the developing apparatus can be improved.

If only the nozzle 20 is used, the nozzle 20 may be moved along the radial direction of the wafer W as described in the first developing method to develop the entire surface of the wafer W. In moving the nozzle 20, it is shown that the nozzle 20 is moved from the upper side of the center part of the wafer W toward the upper side of the peripheral part, but it may be moved in a reverse direction. Developing the entire surface of the wafer W means developing the entire formation region of a semiconductor device. Thus, in performing development using the nozzle 20, the leading end surface of the nozzle 20 is not necessarily disposed on a peripheral end part of the wafer W deviating from the formation region.

The following describes an advantage of supplying the developing solution by a liquid contact nozzle (nozzle having a lower end surface that is brought into contact with the liquid film on the wafer W at the time of processing) such as the nozzle 10 and the nozzle 20 according to the present embodiment as compared with supply of the developing solution by a non-liquid contact nozzle such as the nozzle 30 different from those liquid contact nozzles, for example. The developing solution is locally supplied to the center part of the wafer W while the non-liquid contact nozzle such as the nozzle 30 illustrated in FIG. 11 is disposed at an upper position relatively far from the surface of the wafer W, for example, and the developing solution is spread to be supplied toward the peripheral part by rotation of the wafer W. In the development using such a non-liquid contact nozzle, the developing solution is continuously locally supplied to the center part of the wafer W, so that a difference is caused in progress degrees of development between the center part and the peripheral part of the wafer W, and the uniformity of the pattern within the plane of the wafer W may be lowered.

On the other hand, in both of a case of performing development using one of the two liquid contact nozzles (nozzles 10 and 20) and a case of performing development using both nozzles, the supply position of the developing solution with respect to the surface of the wafer W is moved and the supply position of the developing solution is not fixed. Thus, local progress of development that tends to be caused by the non-liquid contact nozzle is hardly caused by the liquid contact nozzle, and uniformity of the developing process is prevented from being lowered.

The discharge port 12 of the nozzle 10 is not limited to one slit-like opening, but may be formed by disposing a plurality of openings over a length covering the width of the wafer W. In this case, the shape (contour) of the discharge port 12 may be a circular shape, an elliptic shape, a polygonal shape, or a slit-like shape. The same applies to the nozzle 20.

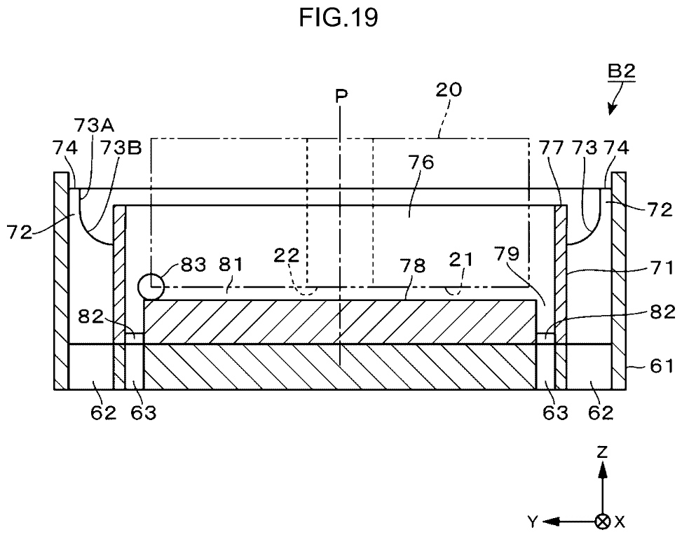

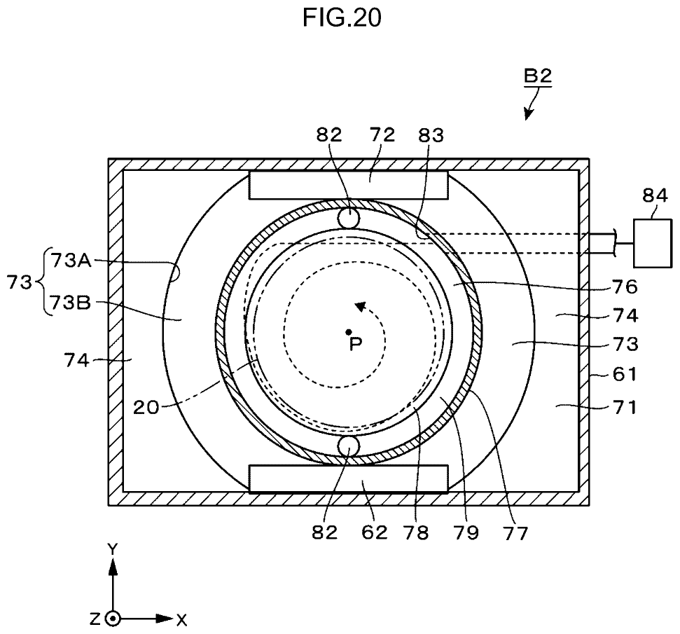

Subsequently, for explaining the nozzle buses B1 to B3 that cause the nozzles 10 to 30 to stand by, the following describes the nozzle bus B2 as a representative thereof with reference to a longitudinal sectional side view in FIG. 19 and a lateral sectional plan view in FIG. 20. In addition to causing the nozzle 20 to stand by as described above, the nozzle bus B2 cleans the nozzle 20 on standby by a cleaning liquid L (not illustrated). Parts of the nozzle 20 to be cleaned are the leading end surface 11 and a lower side of an outside surface that are brought into contact with the liquid film of the developing solution by the developing process described above. The nozzle bus B2 includes a storage part 61 and a cleaning part 71. The storage part 61 is a rectangular box the upper side of which opens, and drain routes 62 and 63 are formed on a bottom wall thereof.

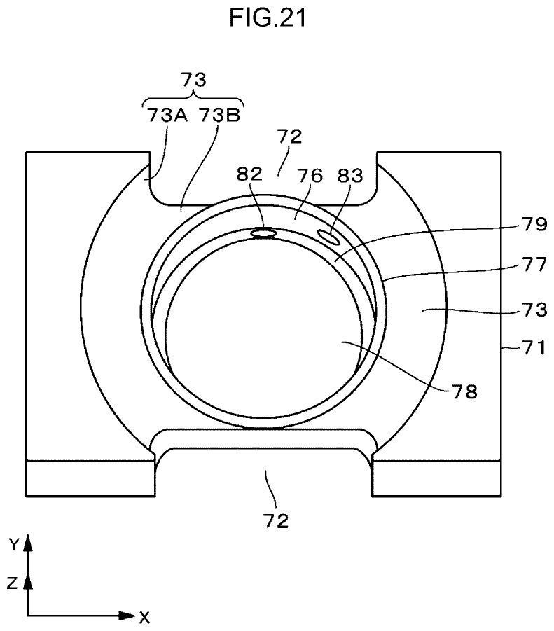

The cleaning part 71 is disposed inside the storage part 61. The description will be continued with reference to FIG. 21 as a perspective view of the cleaning part 71. The cleaning liquid L is supplied between a surface of the cleaning part 71 and a surface of the nozzle 20 on standby. A type of liquid used as the cleaning liquid L is not limited. For example, deionized water is used as the cleaning liquid L, and the cleaning part 71 is formed of fluororesin and the like having relatively high water repellency, for example, to suppress an unnecessary liquid residue after cleaning the nozzle 20.

As illustrated in FIG. 20 and FIG. 21, a schematic shape of the cleaning part 71 is a rectangular thick plate that is horizontally disposed and includes horizontally long notches formed on the front side and the rear side in the Y-direction, and the notches are formed to be respectively positioned at a center part of a side on the front side in a plan view and a center part of a side on the rear side. As illustrated in FIG. 19, a bottom surface of this thick plate is disposed on the bottom wall of the storage part 61, and an outside surface of the thick plate is in contact with an inside surface of the storage part 61, so that the notches on the front and rear sides described above open upward and form a drain port 72 communicating with the drain route 62. Grooves 73 having an arc shape in a plan view are respectively formed on the left and right of an upper surface of the thick plate, and two arcs formed by the grooves 73 form part of a circle centered on the center of the thick plate. Both ends of the groove 73 on the left side are connected to end parts on the left side of respective drain ports 72, and both ends of the groove 73 on the right side are connected to end parts on the right side of the respective drain ports 72. In FIG. 20, the center of the circle described above is denoted as P, and the upper surface of the thick plate outside the groove 73 is denoted as 74.

As illustrated in FIG. 19, a side surface of the groove 73 is formed of a descending surface 73A descending from the thick plate upper surface 74 substantially in a vertical direction. A bottom surface of the groove 73 is formed of a curved surface 73B that has an arc shape in a lateral view and formed to be lower toward the center P to increase the depth of the groove 73, and the curved surface 73B is continuous to the descending surface 73A. In this way, the groove 73 is formed so that the center P side is deeper than the thick plate upper surface 74 side, so that the cleaning liquid overflowed from a recessed part 76 (described later) to be supplied to the groove 73 flows toward the drain port 72 without running on the thick plate upper surface 74.

At the center part of the thick plate, the recessed part 76 having a circular shape is formed to be centered on the center P described above in a plan view. Due to the formation of this recessed part 76, the outside of the recessed part 76 is configured as an annular wall 77, and an outside surface of the annular wall 77 forms a side surface on the center P side of the groove 73 described above. A side surface of the recessed part 76 extends in the vertical direction. An upper end of the recessed part 76 (upper end of the annular wall 77) is lower than the thick plate upper surface 74.

The recessed part 76 forms a space for accommodating the nozzle 20 on standby, and the nozzle 20 enters the recessed part 76 and retreats from the recessed part 76 when the moving mechanism 24 performs lifting/lowering operation. Part of a bottom surface of the recessed part 76 bulges to form a circular platform 78 and an annular groove 79 surrounding this platform 78. The center of the platform 78 in a plan view is the center P, and an upper surface of the platform 78 forming a horizontal plane is positioned to be lower than a lower end of the groove 73. A diameter of the platform 78 is larger than an outer diameter of the leading end surface 21 as the lower surface of the nozzle 20.

FIG. 19 illustrates the nozzle 20 on standby with two-dot chain lines, and FIG. 20 illustrates the lower surface of the nozzle 20 on standby with two-dot chain lines. An upper end of the recessed part 76 is formed to be lower than an upper surface of the nozzle 20 on standby and higher than the upper surface of the platform 78, and a side surface and a bottom surface of the recessed part 76 surround a lower side of the nozzle 20 on standby. The leading end surface 21 of the nozzle 20 on standby is opposed to the upper surface of the platform 78, and a gap 81 is formed between the leading end surface 21 of the nozzle 20 and the upper surface of the platform 78. The center of the leading end surface 21 of the nozzle 20 on standby is aligned with the center P in a plan view, and the leading end surface 21 of the nozzle 20 does not protrude from the upper surface of the platform 78 in a plan view. A position of the nozzle 20 on standby is assumed to be a standby position.

Drain ports 82 are opened at two points on the front side and the rear side of the bottom surface of the annular groove 79, and each of the drain ports 82 is connected to the drain route 63 disposed in the storage part 61. On the side surface of the recessed part 76, a discharge port 83 for the cleaning liquid is opened on an upper side of the upper surface of the platform 78. The cleaning liquid L is supplied from a cleaning liquid supply mechanism 84 to the cleaning part 71, and the cleaning liquid L is discharged from the discharge port 83 into the recessed part 76 via a flow channel formed in the cleaning part 71 and the storage part 61. The cleaning liquid supply mechanism 84 includes a valve that controls supply/interruption of the cleaning liquid to the discharge port 83 by opening/closing, a flow volume adjusting mechanism that adjusts a supply amount of the cleaning liquid L to the discharge port 83, and the like.

As a supplementary explanation about the discharge port 83, the discharge port 83 is formed to be able to supply the cleaning liquid L to the gap 81 on the platform 78. An extension line in the opening direction of the discharge port 83 runs along a diameter of the recessed part 76 in a plan view, but is positioned to be displaced from the diameter. Thus, the cleaning liquid L discharged from the discharge port 83 hits the side surface of the recessed part 76, and flows counterclockwise in a plan view along the side surface to form a swirl flow that is swirling. In FIG. 20, an arrow of a dotted line indicates the flow of the cleaning liquid L. The reason for forming the swirl flow as described above is to form a relatively large liquid flow in the entire gap 81 formed by the leading end surface 21 of the nozzle 20 described above, and efficiently clean the leading end surface 21.

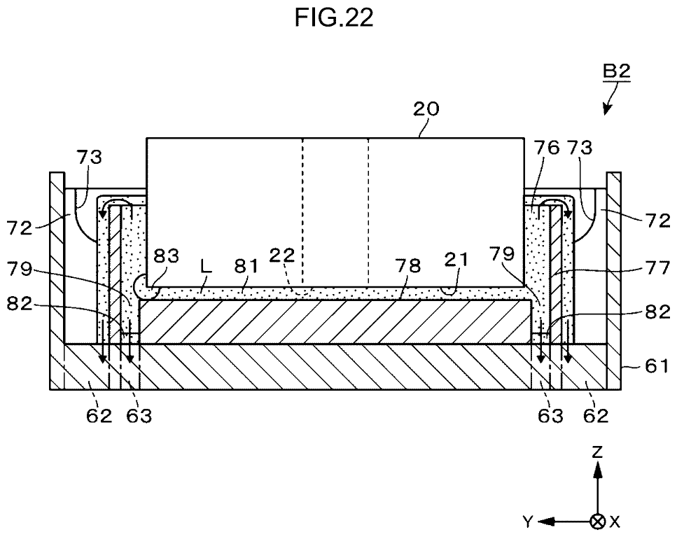

The following describes the cleaning process of the nozzle 20 by the nozzle bus B2 with reference to a longitudinal sectional side view of the nozzle bus B2 in FIG. 22. When the cleaning liquid L is supplied from the cleaning liquid supply mechanism 84 to the discharge port 83, and discharged from the discharge port 83 in a state in which the nozzle 20 is positioned at the standby position, the swirl flow is formed in the gap 81 between the nozzle 20 and the platform 78 in the recessed part 76, and the leading end surface 21 of the nozzle 20 is cleaned.

Part of the cleaning liquid L that is supplied as described above flows to the drain port 82 of the annular groove 79 to be removed from the recessed part 76, but when a supply amount of the cleaning liquid L from the discharge port 83 is adjusted to be larger than a discharge amount from the drain port 82, a liquid surface of the cleaning liquid L in the recessed part 76 rises. Part of the cleaning liquid L overflows from the recessed part 76 to the groove 73, and flows from the groove 73 to the drain port 72 to be removed.

Due to influence of the swirl flow formed in the gap 81, the cleaning liquid L flows relatively largely in a circumferential direction of the recessed part 76 in a region close to the liquid surface in the recessed part 76. Due to overflowing from the recessed part 76, a liquid flow from the lower side toward the upper side is formed in addition to the liquid flow in the circumferential direction. A side surface of the nozzle 20 is cleaned by being immersed in the cleaning liquid L. In addition to being immersed, this cleaning efficiently proceeds due to working of the liquid flow. After a predetermined time has elapsed, discharge of the cleaning liquid L from the discharge port 83 stops, and the cleaning process ends. The cleaning liquid L accumulated in the recessed part 76 is removed through the drain port 82 of the annular groove 79. Thereafter, the nozzle 20 is reused for the developing process.

Before the reuse, the developing solution may be discharged from the discharge port 22 to the gap 81 at the standby position. This is an operation for preventing, by removing the cleaning liquid L attached to the leading end surface 21 of the nozzle 20 by the developing solution that is discharged and spreads on the platform 78 to be brought into contact with the leading end surface 21 of the nozzle 20, the developing solution forming the liquid film P2 from being diluted by the cleaning liquid L when the leading end surface 21 of the nozzle 20 is brought into contact with the discharged liquid film P2 immediately after the reuse.

The following supplements the liquid flow of the cleaning liquid L during the cleaning process described above. As described above, the drain port 82 is formed on the annular groove 79 in the recessed part 76, and the cleaning liquid L supplied onto the platform 78 flows to the drain port 82 to be removed. That is, the liquid flow from the platform 78 to the annular groove 79 is formed. Thus, the cleaning liquid L, which is brought into contact with the leading end surface 21 of the nozzle 20 to contain a contaminant attached to the leading end surface 21 and flows to the annular groove 79, tends to directly flow to the drain port 82 relatively easily, and is prevented from flowing to run onto the platform 78 again against gravity. That is, due to the drain port 82 disposed to be lower than the upper surface of the platform 78 on which the swirl flow is formed, the contaminant can be prevented from being attached to the leading end surface 21 of the nozzle 20 again, and cleaning proceeds rapidly. As disposition of the drain port 82, from the viewpoint of preventing the contaminant from being attached thereto again, it is preferable not to dispose the drain port 82 on the upper surface of the platform 78 as in the configuration example described above. As described above, the leading end surface 21 of the nozzle 20 does not protrude from the upper surface of the platform 78 in a plan view. With such a configuration, the contaminant can be more securely prevented from being attached to the entire leading end surface 21 of the nozzle 20 again.

As described above, the discharge port 83 for the cleaning liquid opens at the height of the gap 81. By opening at this height position, a flow speed of the swirl flow formed below the nozzle 20 becomes relatively high, and cleaning performance of the leading end surface 21 of the nozzle 20 is improved. From the viewpoint of increasing the flow speed in this way, only an upper side of the discharge port 83 may open at the height of the gap 81, and a lower side thereof may be positioned at the height of the annular groove 79 (lower than the upper surface of the platform 78). However, from the viewpoint of preventing the contaminant from being attached to the nozzle 20 again without obstructing the liquid flow from the platform 78 toward the annular groove 79 described above, as in the configuration described above, it is preferable that the discharge port 83 is positioned on the upper side of the upper surface of the platform 78 (the lower end of the discharge port 83 is not positioned to be lower than the upper surface of the platform 78).

In the processing example described above with reference to FIG. 22, the cleaning liquid L overflows from the recessed part 76 during cleaning, but the side surface of the nozzle 20 may be cleaned by adjusting the discharge amount of the cleaning liquid L from the discharge port 83 so that the liquid surface of the cleaning liquid L is positioned at an appropriate height in the recessed part 76 without overflowing.

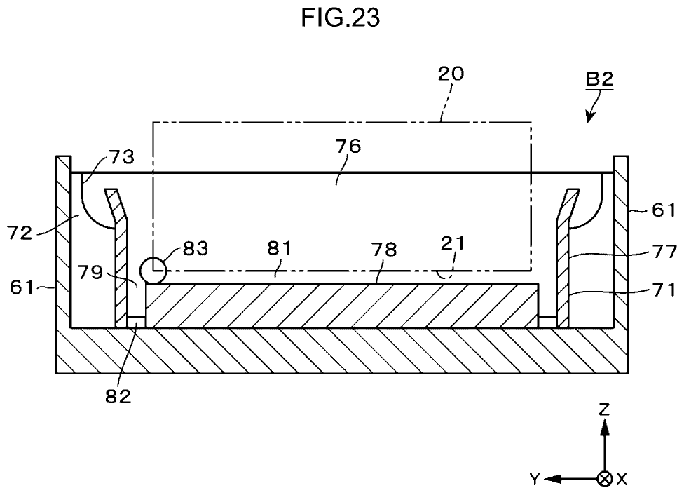

A size in the opening direction of the recessed part 76 may vary so that the cleaning liquid L is prevented from overflowing to the outside of the recessed part 76. In the example of FIG. 23, the annular wall 77 is bent in a vertical cross-sectional view, so that the diameter of the recessed part 76 is increased toward the opening side. The recessed part 76 as described above suppresses rise of the liquid surface of the cleaning liquid L on the upper side, so that the cleaning liquid L is prevented from overflowing.

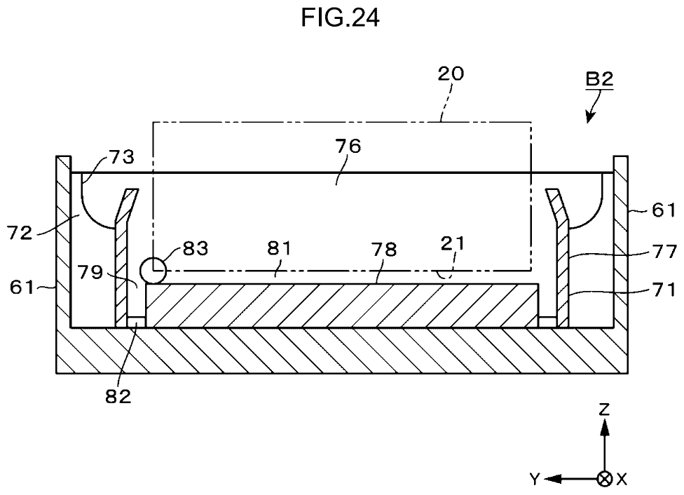

In the example of FIG. 24, the annular wall 77 is bent in a vertical cross-sectional view, so that the diameter of the recessed part 76 is reduced toward the opening side, and the upper end of the annular wall 77 comes close to the side surface of the nozzle 20. Due to this, a pressure loss of the cleaning liquid L is high in the gap between the annular wall 77 and the nozzle 20, so that the cleaning liquid L is prevented from flowing through the gap and removed through the drain port 82 in the recessed part 76, and the cleaning liquid L is prevented from overflowing. In a case of the configuration of performing processing while preventing the cleaning liquid L from overflowing from the recessed part 76 as described above, the groove 73 and the drain port 72 disposed outside the recessed part 76 in the nozzle bus B2 are not necessarily disposed. In a case of a configuration of performing processing while allowing the cleaning liquid L to overflow from the recessed part 76, the drain route 63 and the drain port 82 disposed in the recessed part 76 are not necessarily disposed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A developing apparatus comprising:
a chuck that holds a substrate;
a first nozzle including a first discharge port for a developing solution extending in a lateral direction over a length covering a width of the substrate;
a lifter that causes a first state in which the first nozzle is moved in a direction intersecting with an extending direction of the first discharge port during discharge of the developing solution from the first discharge port to the substrate;
a first liquid contact surface that forms an opening edge part of the first discharge port and is in contact with a liquid film of the developing solution formed on the substrate in the first state;
a second nozzle including a second discharge port for the developing solution in which a length in the extending direction of the first discharge port is formed to be shorter than the first discharge port;
a rotation mechanism, including a rotating shaft, that rotates the chuck to cause a second state in which the substrate is rotated during discharge of the developing solution from the second discharge port to the substrate; and
a second liquid contact surface that forms an opening edge part of the second discharge port and is in contact with the liquid film of the developing solution formed on the substrate in the second state.

2. The developing apparatus according to claim 1, wherein
a plurality of the chucks are disposed separately in a left and right direction,
a first standby part for causing the first nozzle to stand by is disposed between the chucks in the left and right direction, and
a second standby part for causing the second nozzle to stand by is disposed for each of the chucks on any one of the left and right of the chuck.

3. The developing apparatus according to claim 1, wherein
a first nozzle bus that causes the first nozzle to stand by and a second nozzle bus that causes the second nozzle to stand by are disposed, and
a moving region in a lateral direction in a moving route between the first nozzle bus for the first nozzle and a discharge position of the developing solution on the substrate is positioned on an upper side of a moving region in the lateral direction in a moving route between the second nozzle bus for the second nozzle and the discharge position of the developing solution on the substrate.

4. The developing apparatus according to claim 1, wherein
a second nozzle bus that causes the second nozzle to stand by is disposed, and
the second nozzle bus includes:
a recessed part in which an upper end of a side wall is positioned on an upper side of a lower surface of the second nozzle on standby to surround a lower side of the second nozzle; and
a supply port that opens in the recessed part and supplies a cleaning liquid to clean the second liquid contact surface and a side surface of the second nozzle.

5. The developing apparatus according to claim 1, wherein a controller is disposed to output a control signal so that any one and the other one of the first state in which the first liquid contact surface is in contact with the liquid film of the developing solution and the second state in which the second liquid contact surface is in contact with the liquid film of the developing solution are formed in order on the same substrate.

6. A developing method comprising:
holding a substrate by a chuck;
causing a developing solution to be discharged from a first discharge port that is disposed to extend in a lateral direction over a length covering a width of the substrate in a first nozzle;
causing a first state in which the first nozzle is moved in a direction intersecting with an extending direction of the first discharge port by a lifter during discharge of the developing solution from the first discharge port to the substrate;
causing a first liquid contact surface forming an opening edge part of the first discharge port to be in contact with a liquid film of the developing solution formed on the substrate in the first state;
causing the developing solution to be discharged from a second discharge port in which a length in an extending direction of the first discharge port is formed to be shorter than the first discharge port in a second nozzle;
causing a second state in which the chuck is rotated by a rotation mechanism including a rotating shaft, and the substrate is rotated during discharge of the developing solution from the second discharge port to the substrate; and
causing a second liquid contact surface forming an opening edge part of the second discharge port to be in contact with a liquid film of the developing solution formed on the substrate in the second state.

7. The developing method according to claim 6, wherein
a plurality of the chucks are disposed separately in a left and right direction, and
the developing method comprises:
causing the first nozzle to stand by in a first nozzle bus disposed between the chucks in the left and right direction; and
causing the second nozzle to stand by in a second nozzle bus disposed for each chuck on any one of the left and right of the chuck.

8. The developing method according to claim 6, comprising:
causing a first nozzle and a second nozzle to stand by respectively in a first nozzle bus and a second nozzle bus, wherein
a moving region in a lateral direction in a moving route between the first nozzle bus for the first nozzle and a discharge position of the developing solution on the substrate is positioned on an upper side of a moving region in the lateral direction in a moving route between the second nozzle bus for the second nozzle and the discharge position of the developing solution on the substrate.

9. The developing method according to claim 6, comprising:
causing the second nozzle to stand by in a second nozzle bus, wherein
the second nozzle bus includes a recessed part in which an upper end of a side wall is positioned on an upper side of a lower surface of the second nozzle on standby to surround a lower side of the second nozzle, and
the developing method comprises supplying a cleaning liquid to a supply port opening in the recessed part to clean the second liquid contact surface and a side surface of the second nozzle.

10. The developing method according to claim 6, comprising:
forming any one or the other one of the first state in which the first liquid contact surface is in contact with a liquid film of the developing solution and the second state in which the second liquid contact surface is in contact with a liquid film of the developing solution in order on the same substrate.

11. A non-transitory computer-readable recording medium having stored therein a computer program used for a developing apparatus that develops a substrate, wherein the computer program incorporates steps for executing the developing method described in claim 6.
